(19) United States
(12) Patent Application Publication
(10) Pub. No.: US 2010/0013036 A1
(43) Pub. Date: Jan. 21, 2010

(54) Thin Sacrificial Masking Films for Protecting Semiconductors From Pulsed Laser Process

(76) Inventor: James E. Carey, Waltham, MA (US)

Correspondence Address: PEPPER HAMILTON LLP, ONE MELLON CENTER, 50TH FLOOR, 500 GRANT STREET, PITTSBURGH, PA, 15219, US

(21) Appl. No.: 12/173,903

(22) Filed: Jul. 16, 2008

(51) Int. Cl. H01L 31/09; H01L 21/26

(52) U.S. Cl. 257/431; 438/514; 257/E21.328; 257/E31.093

(57) ABSTRACT

The present disclosure is directed to systems and methods for protecting a semiconductor product or material from harmful effects of pulsed laser irradiation. In some embodiments, a thin sacrificial protective mask layer that expires after one laser processing operation is applied to the surface of the product or material to be laser-treated. The thin protective mask layer reflects, absorbs, or otherwise protects the underlying product or material from the energy of the laser.

### I. TECHNICAL FIELD

The following disclosure relates to using a mask for protecting circuitry and elements of a semiconductor product from the effects of a laser, including pulsed a pulsed laser, used in doping the semiconductor.

### II. RELATED APPLICATIONS

N/A

### III. GOVERNMENT FUNDING

N/A

### IV. BACKGROUND

Semiconductor devices, components, and elements, including optical and photo-detecting varieties are entering an ever-wider range of home, laboratory, commercial, industrial, scientific, medical, communication, and military uses. Applications using photo-detecting semiconductors range from missile defense to children's toys. The basic P-N junction and PIN diode has been adapted and extended to enable semiconductor-based photodiodes, photodetectors, photoconductors, charge-coupled devices, photomultipliers, and others, which are herein collectively referred to as photo-detecting semiconductor devices to the extent a variety of these devices can detect photonic activity.

Photo-detecting semiconductor devices share a general characteristic in that they are affected by and provide some response to interaction with electromagnetic radiation. Of the electromagnetic radiation detectable by photo-detecting semiconductor devices, some is in the visible range of wavelengths (approximately 400 nm to 700 nm). Other devices can detect non-visible infrared wavelengths (longer than about 700 nm). The infrared spectrum is sometimes thought of as including a near infrared portion of the spectrum, including wavelengths of approximately 700 to 1300 nm, a mid infrared portion of the spectrum, including wavelengths of approximately 1300 nm to 3 micrometers, and a deep infrared (or thermal infrared) portion of the spectrum, including wavelengths greater than about 3 micrometers up to about 30 micrometers. These are generally and collectively referred to herein as “infrared” portions of the electromagnetic spectrum unless otherwise noted.

A given device's response to its interaction with electromagnetic radiation is influenced by a variety of manufacturing and physical factors, including: the device's size, geometry, material composition, its semiconductor purity (or lack thereof), if doped, the type of dopant used, the concentration of the dopant, the surface treatment of the semiconductor. In addition, manufacturing and environmental factors affect the response of a device, such as ambient temperature, the wavelength and intensity of the electromagnetic radiation interacting with the device. Furthermore, the system in which the photo-detecting semiconductor device is placed (e.g., an electrical circuit) can be designed to apply an electrical bias across the device that affects the device and influences an electrical output obtainable therefrom. Therefore, photo-detecting devices can be generally considered as detectors of the specific wavelength or magnitude of radiation interacting with the devices, and can be adapted to provide functions on the basis of the detected radiation for use in higher-level systems employing the photo-detecting semiconductor devices.

One technique used to treat semiconductor materials to enhance their performance has been to subject some or all of a semiconductor to pulsed laser light, for example in the presence of a dopant, to achieve a special doping characteristic. However, in some cases the semiconductor or semiconductor substrate contains elements that could be damaged by the laser irradiation. Present optical masks made up of dielectric stacks that reflect laser light operate similar to lithography masks. This type of masking is expensive and does not allow for rapid changes in mask design because of the complexity in making a dielectric stack reflector, which is often grown on top of the substrates. This problem is especially acute in high production volumes.

There still remains a need for low-cost, versatile way to protect semiconductor substrates in an environment of laser and other radiation that could damage the substrate or the circuit elements on or in the substrate.

### V. SUMMARY

The present disclosure is directed to thin protective masking layers that provide the ability to carefully and accurately protect areas of an underlying materials and structures from high-intensity short-duration pulsed laser light.

In one embodiment, the present disclosure provides a method for treating a semiconducting product comprising forming a protective mask layer on at least a first area of a surface of the semiconducting product; applying a pulsed laser light source to the semiconducting product and the protective mask layer; and removing the protective mask layer from the surface of the semiconducting product. The mask being a single-use sacrificial mask which is discarded or destroyed after one laser processing treatment of the product.

The forming a protective mask layer on at least a first area of the surface includes evaporating a protective film material onto the first area of the surface in some embodiments, or sputtering a protective film material onto the first area of the surface in other embodiments, or a combination thereof.

Some embodiments include steps of determining a pattern onto which to form the protective mask layer and applying the protective mask layer to said first area determined by said pattern. The pattern can be lithographically selected or applied using a lift-off or cutout technique.

In some embodiments, the protective mask films protect the underlying structures and articles of manufacture from short-duration (e.g., femtosecond or picosecond) pulsed laser light. In other embodiments, the pulsed laser light is of sufficient intensity or power to cause chemical or structural modification of a property of the irradiated material or product in regions not covered by a protective mask layer.

In yet other embodiments, a second protective mask layer is applied to at least a second area of the surface, sometimes applied to a different spatial area, which may or may not overlap or coincide with the first area.

The protective mask layer in some embodiments includes a thin metal layer such as aluminum or gold or titanium, or a combination or alloys thereof. By thin it is generally referenced to the semiconductor process in use and for example in CMOS processes the thin metal layer can be thinner than about 10 microns, and in some instances even thinner than about 1 micron. In addition, the protective layer can include semiconducting or polymeric material. Some embodiments provide a protective mask layer comprising an optically transparent protective mask layer.

In addition, embodiments hereof include applying a dopant material to the semiconducting product while applying the pulsed laser to said semiconducting product.

Still other embodiments hereof are directed to an article of manufacture, including a semiconducting base layer having a surface thereof; a first area of said surface being covered by a thin protective mask layer applied thereto; a second area of said surface being not covered by said thin protective mask layer; a first portion of said surface within said second area of said surface being microstructurally or materially altered by a short-duration pulsed laser light; and a second portion of said surface within said first area of said surface being substantially unaltered by said short-duration pulsed laser light.

In other embodiments, the article of manufacture has regions not covered by the mask layer and exposed to pulsed laser light, the exposed regions being of a predetermined size and shape.

In yet other embodiments, the article of manufacture includes portions proximal to the surface of the semiconducting base which are doped by a dopant.

### VI. BRIEF DESCRIPTION OF THE DRAWINGS

FIG. 1 illustrates an exemplary cross-sectional view of a semiconductor product or material having a protective mask applied to areas thereof and being subjected to a pulsed laser light;

FIG. 2 illustrates an exemplary high-level description of a process for protecting and treating semiconducting products and materials;

FIG. 3 illustrates an exemplary semiconductor product prepared for laser treatment with one or more sacrificial protective mask layers;

FIG. 4 illustrates the product of FIG. 3, where a laser source irradiates the product with an appropriate wavelength and intensity level and pulse frequency of laser light;

FIG. 5 illustrates the product following the laser treatment of FIG. 4 with the sacrificial layer being exhausted, depleted, or degraded, but not necessarily completely so; and

FIG. 6 illustrates the product after the remains of the protective mask layers and the etch stop have been removed.

### VII. DETAILED DESCRIPTION

As alluded to above, many applications in a variety of industries could benefit from new, redesigned, and more versatile photo-detecting devices, e.g., more sensitive photo-detecting semiconductor devices, and photo-detecting semiconductor devices that can operate in previously-unknown regimes. These devices and systems employing the devices can open up a new vista of applications and uses and markets for the devices and systems employing the devices.

Some embodiments of systems using laser-enhanced photo-detecting semiconductor components includes those sensing and providing substantial electrical responses to photonic radiation (light) both in a visible portion of the electromagnetic spectrum as well as outside the visible portion of the electromagnetic spectrum. These embodiments use a single detector device for detecting both the visible and non-visible (e.g., infrared) radiation instead of using separate detectors for each of the visible and the non-visible radiation, and enable for example same-detector imaging or photography under both day and night (low-light) conditions.

The techniques for producing semiconductor devices having these new and advanced properties sometimes employ irradiation of the semiconductor with pulsed (e.g., picosecond and femtosecond pulsed) laser light, and for example in the presence of dopants. The resulting material is sometimes referred to as “Black Silicon” and is described in various patent applications by the present inventors and assignees. This disclosure is directed to, inter alia, using thin film protective masks applied directly or substantially directly onto the semiconductor substrate. The thin film masks are robust and compatible with large scale semiconductor processing techniques. The thin film masks enable spatial limitation of the incident laser light to small areas with great precision. The thin films are inexpensive to apply and incorporate into an existing semiconductor processing operation. In some cases, the present thin films are designed to tolerate very short burst laser treatments (e.g., picosecond or femtosecond pulsed lasers) but would not tolerate longer pulses of laser (e.g., nanosecond pulsed lasers). However, the nature of the invention is not intended to be limited to only pico or femtosecond pulsed lasers, and comprehends other pulsed laser systems, depending on the other design parameters of the laser, film, semiconductor, and overall context in which these are used.

In some aspects, the non-linear absorption of the present high-intensity short-pulse laser allows for thin film designs to provide the above and other features. Non-linear absorption takes place in a reduced depth of material compared to linear absorption due to the increased deposition of energy in non-linear absorption scenarios compared to linear absorption scenarios. Therefore, a shallower absorption layer can suffice to protect the underlying semiconductor material and components from the laser in the case of non-linear absorption. In addition, non-linear absorption can allow absorption of wavelengths in a solid material that are otherwise (in the linear regime) transparent to the same wavelengths.

Embodiments hereof include thin films of protective materials, including metal protective films. In specific embodiments, the thin protective metal films can comprise aluminum films. In still more specific embodiments, the thin protective metal aluminum films can be approximately 1 micrometer (μm) in thickness.

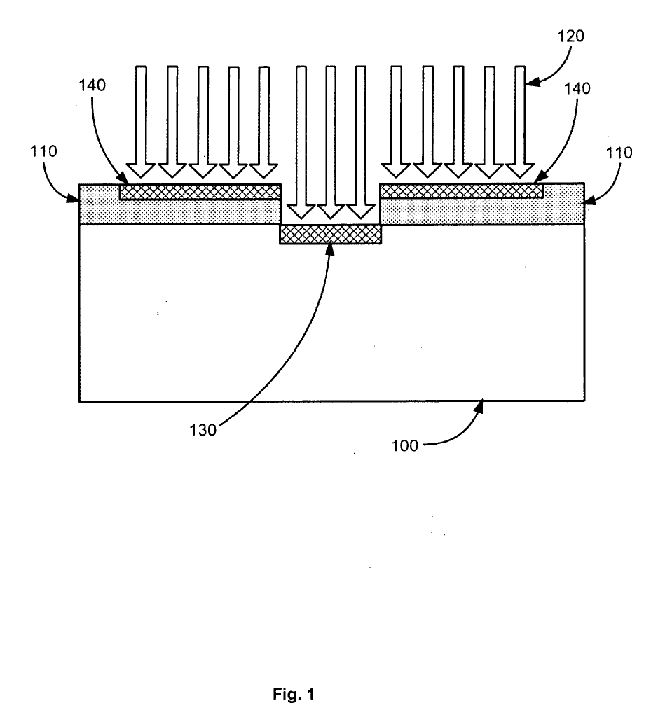

FIG. 1 illustrates an exemplary cross-sectional view of a semiconductor product or material having a protective mask applied to areas thereof and being subjected to a pulsed laser light. A semiconductor substrate 100 (e.g., silicon or silicon-based substrate) has a surface onto which a protective thin layer mask 110 as described herein is applied. A high-intensity pulsed laser beam or light 120 is incident onto the product or device such that a surface area of protective mask 110 is affected by the laser 120. For example, a region 140 of some depth within protective mask 110 is affected by the laser light 120.

Also, a region 130 of some depth on the surface of the semiconductor substrate 100 is affected by the laser light 120. The shape and size of the area 130 of substrate 100 can be designed and engineered as described herein according to the shape and size of the protective mask 110.

The thin protective film masks 140 can comprise optically transparent or opaque materials, including polymers. In some preferred embodiments, the material is optically opaque or non-transparent. For example, a polyimide or a photoresist material can be laid onto the underlying semiconductor device or circuitry or components to be protected from pulsed laser irradiation. Following the laser irradiation, some or all of the above thin protective masks can be removed using semiconductor processing techniques. Examples include chemically removing (etching) the polymer based masks, e.g., a photoresist strip processing step; lift off or chemical or physical etch of metal masks; and chemical or physical etch of semiconductor masks.

Certain thin protective mask films can have a reflective property that effectively blocks the pulsed laser light from passing into or through the protective film. Protection can be afforded by the instant thin films in some conditions because the incident laser would only substantially affect a top or surface portion of the protective metal film. The top or surface portion of the protective film can be melted or ablated by the laser, but the underlying material or components remain substantially unharmed or unaffected by the incident laser. Therefore the damaging effects of the laser are effectively blocked by the thin protective film.

Some or all of the above techniques provide the ability to carefully and accurately apply the mask to protect the underlying materials and structures from high-intensity short-duration pulsed laser treatments. The thin protective films can be applied by evaporative methods or sputtering. For definition of the areas to which the thin films are applied (or not applied) a lithographic or lift-off or contact cutting technique can be used.

The fact that the instant protective layers are thin provides some advantages when used in the context of CMOS processing flows, the mask thicknesses are compatible with CMOS processing and are thin enough to not cause optical effects (diffraction problems) on small area devices, for example being thinner than approximately 10 or even 1 micrometer. Also, lateral feature size can be controlled and reduced because of the well-defined patterning of the thin film masks. Diffraction effects and shadow effects are reduced so that little or no blurring or geometric or spatial distortion of the intended mask area takes place. In some embodiments, lateral dimensioning on the order of 1 micrometer (μm) is possible, and even greater accuracy is possible, depending on the laser wavelength, mask thickness, and other factors.

In one specific embodiment, a single metal thin film protective mask (such as aluminum, copper, gold, chromium, titanium, tungsten, or other suitable metal) is applied to a semiconductor product or wafer. The thin film may be applied by sputtering or evaporation. In one embodiment, the thin film protective mask is built up to approximately 2 micrometers (μm) in thickness. The film is applied to the surface of a semiconductor device or wafer material which is to face or be subjected to a laser processing step. Proper dimensioning and patterning of the thin protective film is accomplished to properly mask the area(s) to be protected or left unprotected. The semiconductor device or material is subjected to a pulsed laser irradiation treatment (e.g., picosecond or femtosecond laser pulses). Following treatment with the laser, but not necessarily immediately following the laser treatment, the thin film is removed using semiconductor processing techniques. Other steps may be included before, after, or in between those described. Therefore, in some embodiments, the protective mask layer expires after a single (one) laser processing operation or step to the semiconductor product and cannot be re-used to mask another (second) product during laser treatment.

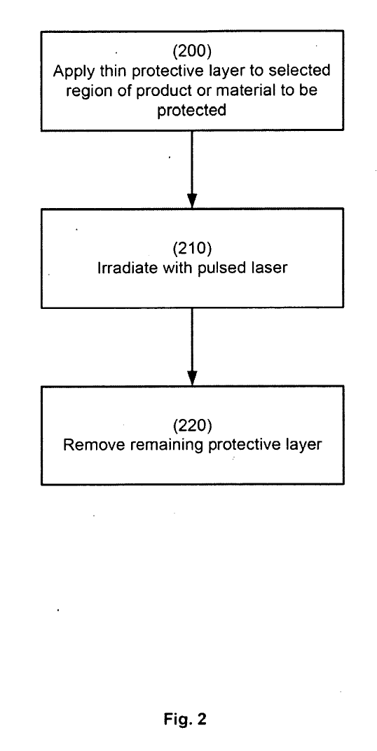

Referring to FIG. 2, an exemplary high-level description of a process for protecting and treating semiconducting products and materials is shown. In step 200 a thin protective layer as described herein is applied to selected regions of a semiconductor product or material to be protected. The product or material, with the protective thin film thereon, is irradiated by a high-intensity short-duration pulsed laser to one or more regions of the product or material in step 210. The protective film masks the regions of the product or material to which it was applied (e.g., by reflection, conduction, absorption). Once the laser treatment of the product or material is complete, the protective thin film layer can be removed in step 220.

In yet other embodiments, the process substantially as given above can be applied but using a combination of alloys of metals and/or semiconductors. In one example, a titanium/aluminum or chromium/gold alloy can be used. In another example, silicide can be used as a thin protective film.

Polymer films can also be employed to define or protect some regions of a semiconductor product or device. Examples of materials that can be used to this end include photoresist, polyimide, silicon nitride, and others. These materials can be substantially transparent to visible light and may not be ideal for absorption of laser light under linear conditions. However, under high-intensity short-duration pulsed laser irradiation, where the absorption is non-linear, these materials can be an effective barrier and absorb the laser's energy before it substantially penetrates the layers to reach the underlying semiconductor product or device. Therefore, a protective mask can comprise one or more layers of a polymer film, a photoresist layer, or a polyimide layer, or a silicon nitride layer, or a combination thereof.

In still other embodiments, a plurality of thin films can be applied as necessary to provide a desired result. The plurality of thin films can be applied to the same or different spatial areas on the surface of the semiconductor product or device. For example, a first layer of a first thickness of a thin metal film can be applied. A second layer of a second metal can be applied on top of the first. A third layer of a third alloy can be applied on top of the first two. A fourth layer of a non-metal (e.g., a semiconducting material or a polymeric material) can be applied to the other three. Obviously, it is intended that any or all situations and combinations to be possible and within the present scope.

It can be advantageous in some situations to use a thin protective film comprising a material that is sacrificial in itself. That is, the thin protective mask material undergoes a transformation as a result of the laser pulses, which can in some instances destroy, remove, ablate, melt, vaporize, or alter the protective film mask. An example of such a sacrificial mask material can include silicon itself. This can be amorphous, crystalline, microcrystalline, or polycrystalline silicon.

The thin film protective mask can include or be made of a material with sufficient thermal conductivity to assist in removal of heat from the laser source to protect the underlying material or product from heat damage in selected protected areas. In one example, a metal thin protective mask is used to conduct and reflect the laser's energy away from an underlying silicon product or material.

Again, the present disclosure is not limited to application of the protective mask layers to the same spatial areas. But in fact, a first layer can be applied to a first region on the surface of the semiconductor product or device, and then a second layer (of the same or another protective film material) can be applied to a second region on the surface of the semiconductor product or device. The coverage regions for the first and second protective film layers can overlap or not overlap at all as required.

Still other embodiments of systems using laser-enhanced photo-detecting semiconductor components includes those employing an array, grid, cluster, or plurality of individual organized laser-enhanced photo-detecting semiconductor devices for detection, imaging, tomography, and other purposes. These embodiments employ a number of individual laser-enhanced semiconductor detector elements as discussed below to form an image, photograph, or video output from the grouped, gridded, organized individual detector elements, which may be addressable to form a two-dimensional output for example.

One illustrative embodiment of a system for detecting both visible and non-visible light with the same detector or grouping of detectors includes a photo-detecting system designed for use in detecting both visible and non-visible light using a single detector device. The system detects and responds to light over a range of wavelengths. For example, the system is responsive to light over a range of wavelengths extending from approximately a shorter wavelength limit (being shorter than about 400 nm) and extending through approximately a longer wavelength limit (being longer than about 700 nm). In this way, the detector system is substantially responsive to light both in a visible portion of the electromagnetic spectrum and to light outside the visible portion of the electromagnetic spectrum.

The following discussion illustrates further a preferred system and method for achieving the advantages recited herein.

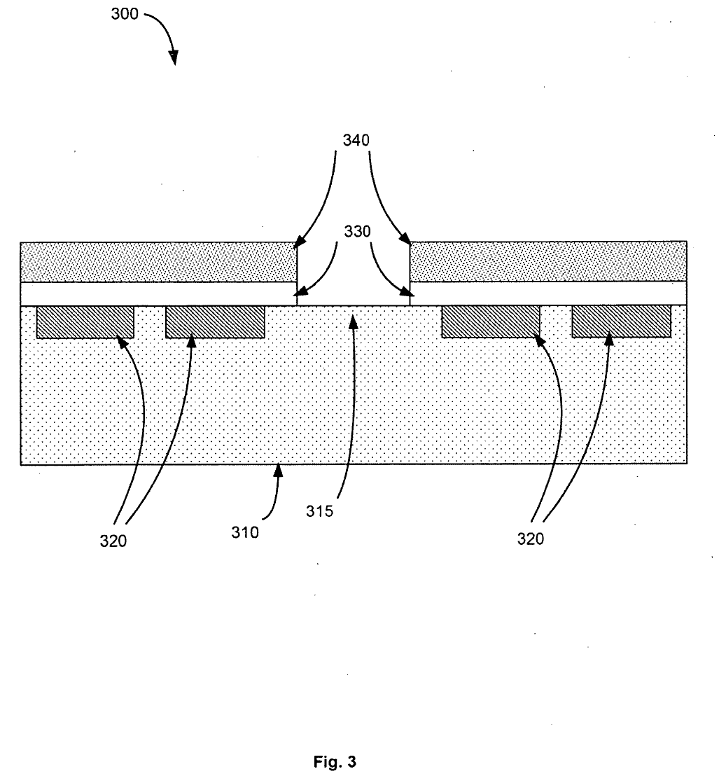

FIG. 3 illustrates an exemplary semiconductor product 300 prepared for laser treatment with one or more sacrificial protective mask layers. Semiconductor product 300 includes a substrate 310 which is for example silicon or silicon based. A portion of the product or substrate is designated as a portion 315 to be irradiated by laser light as discussed earlier. Since only portion 315 is to be irradiated, other portions of the product, including circuitry or components 320 are protected by protective mask layers 330 and 340. Layer 330 may be a silicon dioxide or silicon nitride etch stop or passivation layer that can be removed once it accomplishes its function. Layer 340 is a sacrificial protective layer that provides high, nonlinear, absorption of the pulsed laser to protect what is beneath it. Layer 340 is exhausted after the laser treatment process and is not reusable.

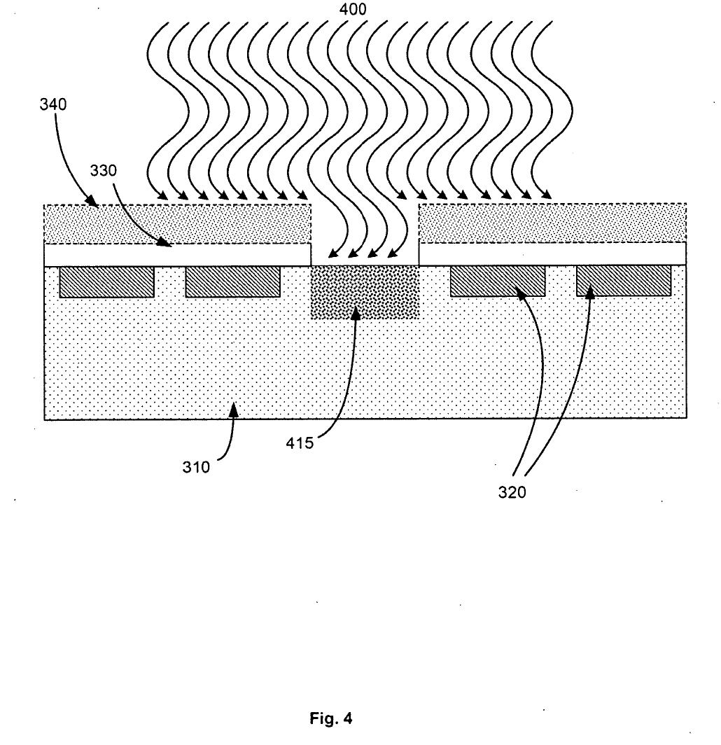

FIG. 4 illustrates the setup described in FIG. 3 above, where a laser source irradiates the product with an appropriate wavelength and intensity level and pulse frequency of laser light 400 to cause the beneficial modification of the semiconductor product in a region 415 exposed to the laser light 400 and not protected by protective thin mask layer 340. Protective sacrificial mask layer 340 is degraded during the laser irradiation process as a result of absorbing and being exposed to the laser light 400.

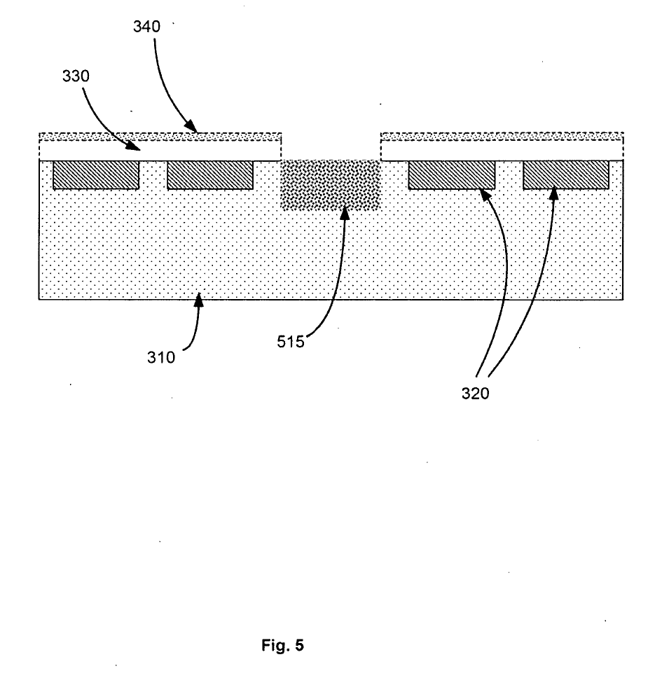

FIG. 5 illustrates the product following the laser treatment of FIG. 4. Here the sacrificial layer 340 is exhausted, depleted, or degraded, but not necessarily completely so. A laser-modified region 515 is now fully formed. Circuits and components 320 have not been adversely affected, nor has substrate 310 because of the shielding by the protective mask layer 340.

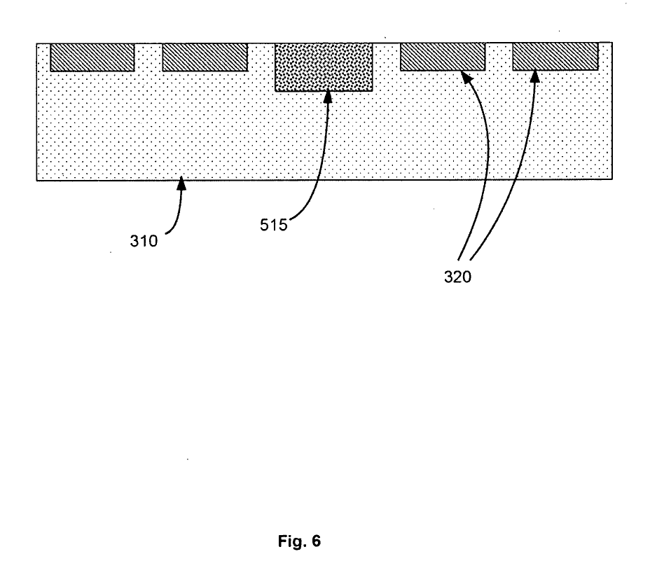

FIG. 6 illustrates the product after the remains of the protective mask layers and the etch stop have been removed. The final product includes the substrate 310 with the circuit or other components 320 and a laser-treated portion 515. Of course additional treatments and layers and processes may be involved during or after the sequence described above.

It is to be appreciated that the responsiveness of the system or its detector element(s) is not necessarily uniform as a function of wavelength. That is, a response curve representing the sensitivity, output level, or other characteristics of the photo-detecting semiconductor can be defined or measured. Corrections can be implemented, with hardware or software, or a combination of both, so that the effects of the variation in response as a function of wavelength may be corrected for, compensated, or otherwise taken into account if desired.

Numerous other embodiments, modifications and extensions to the present disclosure are intended to be covered by the scope of the present inventions as claimed below. This includes implementation details and features that would be apparent to those skilled in the art upon review of the present disclosure and appreciation of the concepts and illustrative embodiments provided herein.

What is claimed is:

1. A method for treating a semiconducting product, comprising:
forming a sacrificial protective mask layer on at least a first area of a surface of the semiconducting product;
applying a pulsed laser light source to the semiconducting product and the protective mask layer; and
removing the protective mask layer from the surface of the semiconducting product.

2. The method of claim 1, said forming a protective mask layer on at least a first area of the surface comprising depositing a protective film material onto the first area of the surface.

3. The method of claim 1, said forming a protective mask layer on at least a first area of the surface comprising sputtering a protective film material onto the first area of the surface.

4. The method of claim 1, said forming a protective mask layer on at least a first area of the surface comprising determining a pattern onto which to form the protective mask layer and applying the protective mask layer to said first area determined by said pattern.

5. The method of claim 1, said applying the pulsed laser light comprising applying a short-duration pulsed laser light.

6. The method of claim 5, said applying the short-duration pulsed laser light comprising applying a laser light at substantially femtosecond pulse durations.

7. The method of claim 5, said applying the short-duration pulsed laser light comprising applying a laser light at substantially picosecond pulse durations.

8. The method of claim 1, further comprising applying a second protective mask layer to at least a second area.

9. The method of claim 8, applying the second protective mask layer comprising applying the second protective mask to an area with different spatial coverage than the first area.

10. The method of claim 1, said forming of the protective mask layer comprising forming a thin metal layer.

11. The method of claim 10, said forming of the thin metal layer comprising forming a thin layer of aluminum.

12. The method of claim 1, said forming of the protective mask layer comprising forming a thin protective layer of metal alloy.

13. The method of claim 1, said forming of the protective mask layer comprising forming a thin semiconducting protective layer.

14. The method of claim 1, said forming of the protective mask layer comprising forming a thin polymeric protective layer.

15. The method of claim 1, said sacrificial protective mask layer expiring after a single laser processing operation on said semiconductor product, and being unusable for masking another semiconductor product.

16. The method of claim 1, further comprising carrying out a lithographic process to form said protective mask layer on said first area.

17. The method of claim 1, said forming of the protective mask layer comprising forming a plurality of lavers, one upon the other, but each not necessarily constrained to the same area of the surface of the semiconducting product.

18. The method of claim 1, the method of treating a semiconducting product comprising a method of treating a silicon substrate.

19. The method of claim 1, applying said laser light comprising applying a high-powered pulsed laser light such as to cause material modification of said semiconducting product in regions not covered by said protective mask layer.

20. The method of claim 1, further comprising applying a dopant material to the semiconducting product while applying the pulsed laser to said semiconducting product.

21. An article of manufacture, comprising:
a semiconducting base layer having a surface thereof;
a first area of said surface being covered by a thin sacrificial protective mask layer applied thereto;
a second area of said surface being not covered by said thin protective mask layer;
said second area of the surface having a region proximate thereto that is altered by a short-duration pulsed laser light; and
said first area of the surface having a region proximate thereto that is substantially unaltered by said short-duration pulsed laser light.

22. The article of claim 21, said first area having a predetermined size and shape.

23. The article of claim 21, further comprising a region proximal to said surface of said semiconducting base being doped by a dopant.

24. The article of claim 21, said thin sacrificial protective mask layer comprising a thin metal layer.

25. The article of claim 24, said thin metal layer comprising a thin layer of aluminum.

26. The article of claim 21, said thin sacrificial protective mask layer comprising a thin layer of metal alloy.

27. The article of claim 21, said thin sacrificial protective mask layer comprising a thin semiconducting protective layer.

28. The article of claim 21, said thin sacrificial protective mask layer comprising a thin polymeric protective layer.
